(19) United States
(12) Patent Application Publication
(10) Pub. No.: US 2012/0268114 A1
(43) Pub. Date: Oct. 25, 2012

(54) CURRENT SENSOR WITH A MAGNETIC CORE

(75) Inventors: Rolf DISSELNKÖTTER, Mauer (DE); Adrian Hozoi, Mannheim (DE)

(73) Assignee: ABB AG, Mannheim (DE)

(21) Appl. No.: 13/451,237

(22) Filed: Apr. 19, 2012

(30) Foreign Application Priority Data
Apr. 21, 2011 (EP) 11003399.1

(51) Int. Cl. G01R 33/04

(52) U.S. Cl. 324/253

(57) ABSTRACT

A current sensor is disclosed, with a ring-shaped magnetic core, the core enclosing the primary conductor with the current to be measured, the core having an air-gap containing a sensor element for measuring the magnetic core induction, whereby the cross-sectional area of the air-gap is larger than the cross-sectional area of the core.

### RELATED APPLICATION

This application claims priority under 35 U.S.C. §119 to European Patent Application No. 11003399.0 filed in Europe on Apr. 21, 2011, the entire content of which is hereby incorporated by reference in its entirety.

### FIELD

The present disclosure relates to a current sensor with a ring-shaped magnetic core, such as a core enclosing a primary conductor carrying current to be measured, the core having an air-gap containing a sensor element for measuring magnetic core induction.

### BACKGROUND INFORMATION

Current sensors of two types, open and closed loop, are able to measure both AC and DC currents. These sensors can feature a soft magnetic, ring-shaped, core, which encloses a primary conductor with current that shall be measured. The core can be composed of either a strip-wound metal tape, stacked magnetic sheet steel or bulk ferrite. The core can have an air gap, which is aligned along the circumferential direction of the core. FIG. 1 shows a known configuration in schematic form. Ring shaped refers to a core having a contour which is nearly closed in the circumferential direction apart from the air gap, which is assumed to be small. Ring-shaped in this sense can, for example, be either a circular, an ovaloid or a rectangular shape.

The direction of the air-gap as referenced herein is the main direction of the magnetic field in the air-gap. The cross-sectional area of the air-gap is the same as the cross-sectional area of the core.

The air-gap contains a sensor element for the measurement of the magnetic core induction, which may be a Hall-sensor, an integrated circuit based Hall sensor, a magnetoresistive sensor or a fluxgate sensor.

Current sensor applications as known apply a flat shaped air gap and a flat-shaped sensor element.

Current sensors operating in accordance with the principle of compensation are often also called closed loop current sensors. If the current sensor is of the closed loop type, the magnetic core is provided with a secondary winding which carries a compensation current. The purpose of the compensation current is to counteract the magnetic flux density generated by the primary current such that nearly zero-flux operation is ensured both at AC and DC. For this purpose a flux sensor element located in the air-gap, will detect any magnetic flux induced in this circuit and will generate a proportional signal. This signal is amplified by some electronic power stage, called booster circuit, which will generate the current through a secondary winding. The secondary current is thus opposed to the primary current, establishing a negative feedback, and will compensate its effect on the magnetic circuit.

Open and especially closed loop current sensors may be rather accurate. However, in multi-phase systems with other conductors and currents there may be an impact on the sensor accuracy from magnetic cross talk. This can be mainly due to the effect of the air-gap, which causes magnetic stray fields from the core induction and at the same time a vulnerability of the current sensor to external magnetic fields.

Magnetic cross-talk sensitivity can be reduced by reducing the magnetic reluctance of the air-gap, which is proportional to the ratio between the length in the direction of the air gap and the cross-sectional area of the air-gap. With known state-of-the art current sensor designs a reduction of the magnetic reluctance is limited in cases when the core has a small core cross section, as the length of the air-gap cannot be reduced below the minimum thickness of the flux sensor element, and the sensor has a certain minimum lateral dimension, such that the flux sensor element may be insufficiently shielded by the core or even protruding from the air gap and thus be exposed to the influence of external stray fields.

### SUMMARY

A current sensor is disclosed, comprising: a ring-shaped magnetic core, said core enclosing a primary conductor for carrying current to be measured, said core having an air-gap; and a sensor element of said air-gap for measuring magnetic core induction, wherein a cross-sectional area of the air-gap is larger than a cross-sectional area of the core.

### BRIEF DESCRIPTION OF THE DRAWINGS

Several configurations are described herein by way of the detailed description and the accompanying drawings, where:

FIG. 1 shows a known core design with a sensor in the air-gap;

FIG. 2 shows a core design with a sensor in an air-gap according to a first exemplary embodiment;

FIG. 3 shows a core design with a sensor in the air-gap according to an exemplary variation of the embodiment shown in FIG. 2;

FIG. 4 shows a core design with a sensor in the air-gap according to a second exemplary embodiment;

FIG. 5 shows exemplary alternative core designs according to the embodiment shown in FIG. 4; and

FIG. 6 shows a core design with a sensor in the air-gap according to a third exemplary embodiment.

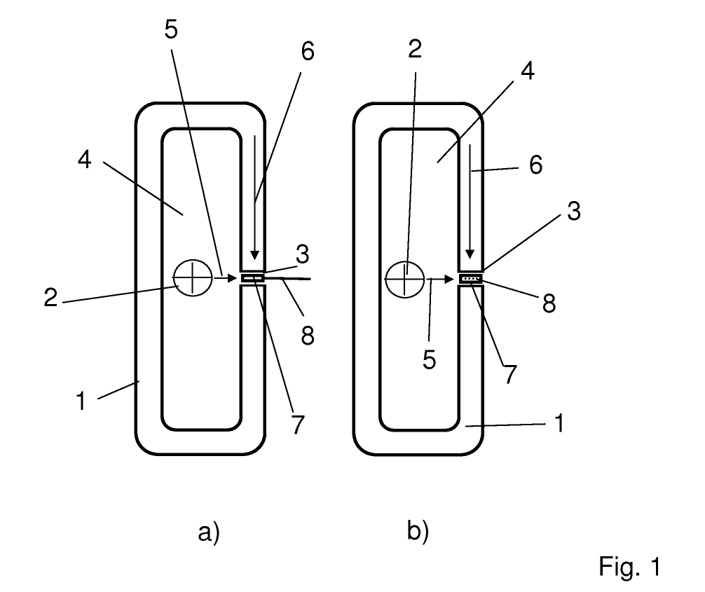

Elements with a same or similar function and mode of operation are provided in the FIGS. 1 to 6 with the same references numbers.

### DETAILED DESCRIPTION

An exemplary current sensor is disclosed with a reduction of the magnetic cross-talk sensitivity, both in an open and in a closed loop configuration, notwithstanding a potentially limited cross-sectional area of the core.

In an exemplary embodiment, a cross-sectional area of an air-gap is larger than a cross-sectional area of a core.

As referenced herein, the cross-sectional area of the air-gap refers, for example, to an area of the cross-section perpendicularly to the direction of the air-gap, whereby the direction of the air-gap is defined as the main direction of the magnetic field in the air-gap. Cross-sectional area of the core refers, for example, to an area of the cross-section of the core perpendicularly to the circumferential direction of the core.

An exemplary advantageous effect of a current sensor design as disclosed herein is that the magnetic reluctance of the air-gap is reduced as far as possible, without a need to significantly increase the cross-sectional area of the core. An exemplary current sensor as disclosed can have a reduced magnetic reluctance of the air gap, whereby any limits due to the thickness of the magnetic sensor element and the size and shape of the magnetic core need not be taken into account.

According to an exemplary embodiment, the direction of the air-gap is oriented in the axial direction of the ring-shaped core. The axial direction is the direction perpendicular to the plane in which the ring-shaped core lies.

According to a further exemplary embodiment, the core has at least one overlap region where a first and a second end piece overlap forming an overlap area when the core is assembled in its ring-shaped form, the overlap region forming the air-gap which is configured to contain the sensor element. The cross-section of the overlap region can be made larger than the cross-section of the core, so also the cross-section of the air-gap formed in the overlap region will be larger than the cross-section of the core.

According to a further exemplary embodiment, the core is composed of a first part and a second part. The first and second parts, when assembled, form the ring-shaped core, and the first and second parts overlap in a first and a second overlap region with a first and a second overlap area, whereby the first overlap region forms the air gap which is configured to contain the sensor element, and whereby the second overlap region provides direct contact between the first and the second part.

The core may be either of a circular, an ovaloid or a rectangular shape. In a preferred exemplary embodiment, the core is composed of at least two parts of a stacked core, made from one or several sheets of magnetic material, which form a ring that encloses the primary conductor and which overlap in two plane regions of the core.

According to a further exemplary embodiment, the first and second overlap regions form first and second gaps, and the first gap is configured as air-gap to contain the sensor element, and the second gap is filled with a soft magnetic spacer means for magnetically short-circuiting the second gap. So, one of the overlaps forms a narrow gap, which contains the sensor element. The other overlap makes good magnetic contact between the two surfaces without intentional formation of an air gap.

According to a further exemplary embodiment, the spacer means is made of a nonmagnetic spacer material or a second flux sensor.

According to a further exemplary embodiment, the overlap area in the second overlap region is larger than the overlap area in the first overlap region. So, by using non-symmetric parts, the overlap in the second overlap region can be made larger than that at the air gap in order to improve the flux transition.

An exemplary advantage of a sensor configuration disclosed herein is that the cross section of the air gap can be larger than the core cross section, and sufficiently large to provide a good coverage and shielding of the sensor element.

In order to simultaneously form a gapped and a non-gapped plane overlap between the first and second core parts during manufacturing, at least one of the core parts may be provided with an out-of-plane bending of the metal sheets which form the stacked core. This bending can be either limited to a small zone of the core or be evenly distributed across the whole length of its circumference, (e.g., in order to minimize either the area or the level of the mechanical distortion, or to keep the major part of the core in the same plane). However, any intermediate case of a bending distribution is also possible.

The metal sheets from which the stacked core is composed can be produced from large coil sheets in a single punch-bending process. For example, they will undergo an annealing process after the mechanical processing in order to restore optimum soft magnetic properties.

The assembled core can then be fixed either by mechanical clamping, riveting, resin impregnation, moulding, taping, or housing in a plastic case, or other suitable means.

The sensor element can be mounted in the air-gap with its connection pins pointing either into the radial, the circumferential or into the axial direction to meet specifications of the application. Such specifications may be, for example, from the process of the formation of a secondary winding or from the mounting of the core in a case or on a printed circuit board (PCB).

In a further exemplary embodiment, two or more core parts, which can be produced from stacked, strip-wound or bulk (e.g., ferrite material), are planar (e.g., unbent). They are mounted on top of each other with two overlap regions, one of which forms a gap while the other one makes a direct contact. This is achieved by tilting one core-part with respect to the other, which leads to a gap and a contact which have end faces that are not fully parallel. In order to keep the inclination small, this method can, for example, be used with elongated cores, where the overlap regions are on the short sides of the core.

In a further exemplary embodiment, the planar core parts are mounted on top of each other with a parallel orientation, such that equal gaps are formed in the overlap regions. The second gap can be filled either with a second sensor, a nonmagnetic spacer or with soft magnetic material, which will magnetically short-circuit the gap. In both configurations, the cross section of the overlap is larger than the core cross section.

In a further exemplary preferred embodiment, the ring-shaped core has a first, ungapped partial core and a second partial core having an air-gap which is oriented in the axial core direction, the air-gap containing a sensor element for measuring the magnetic core induction, whereby the cross-sectional area of the air-gap is larger than the cross-sectional area of the second partial core, first and second partial cores being placed on top of each other and forming a combined magnetic core that can be provided with a common secondary winding. The first partial core may in a further exemplary embodiment have a larger height than the second partial core and can be made from a high saturation magnetic material.

The latter embodiment can be particularly advantageous if the first partial core carrying the flux sensor has a low core height and a high quality, (e.g., high μ, low Hc, core material). The aforementioned types of core designs are suited for putting them on top of a coaxial ungapped core with the same outlines, but with a larger height that is made from a high saturation magnetic material. Together, the two partial cores will then form a combined magnetic core that can be provided with a common secondary winding. By this approach it is possible to build a closed loop current sensor, which will feature at the same time a large dynamic range, low cross-talk and low DC offset.

In a further exemplary embodiment, the direction of the air-gap is oriented in the radial direction of the ring-shaped core. The radial direction is defined as being substantially perpendicular to the axial direction defined above.

In this embodiment, too, the core may have a mainly circular, ovaloid or rectangular shape, and may be made from stacked core sheets or from a few layers of thin strip-wound magnetic tape, which form a ring enclosing the primary conductor. The core may overlap in a plane region of the core, where it forms an air gap that fully encloses the flux sensor element. The core may have curved parts or local bends to generate the specified overlap. It can be fixed by resin impregnation, spot welding, moulding, plastic encapsulation, or other suitable means. The cross section of the overlap can be larger than the core cross section.

In a further exemplary embodiment, the ring-shaped core has a first, ungapped partial core and a second partial core having an air-gap which is oriented in the radial core direction, the air-gap containing a sensor element for measuring the magnetic core induction, whereby the cross-sectional area of the air-gap is larger than the cross-sectional area of the second partial core, one of the two ring cores being located inside the other one, the first and second partial cores forming a combined magnetic core that can be provided with a common secondary winding. The first partial core may in a further exemplary embodiment have a larger radial thickness than the second partial core and can be made from a high saturation magnetic material.

The latter embodiment can be particularly advantageous if the first partial core carrying the flux sensor has a low radial core thickness, the same core height as the second partial core and a high quality (e.g., high μ, low Hc, core material). By this approach it is possible to build a closed loop current sensor, which will feature at the same time a large dynamic range, low cross-talk and low DC offset.

In a further exemplary embodiment, the direction of the air-gap forms an angle with the radial or the axial direction of the ring-shaped core. The angle may be around 45°, but any other angle between 10° and 80° is also possible. The core may be based on strip-wound, stacked or bulk material, which can be fixed by the aforementioned methods.

Summarising, some of the exemplary advantages of the described solutions are:
Large air gap cross sections can be achieved at small core cross sections.
The sensor element can be better protected from external magnetic interference.
Full sensor coverage can be achieved for small core cross sections.
Space and material is saved if only small core cross sections are involved.
The air gap can be oriented along directions where interfering fields are smaller.

The present disclosure describes exemplary configurations of the core and of the air-gap aimed to reduce the cross-talk sensitivity by providing a more convenient gap orientation and reducing the magnetic reluctance of the gap beyond any limitation due to the cross-section of the core.

FIG. 1 shows schematically a known magnetic core design 1 for a closed loop current sensor. The current sensor is based on a magnetic circuit having the magnetic core 1 of a highly permeable material. The magnetic core 1 encloses a primary conductor, here indicated by the circle with cross 2, which carries the current that is to be measured. The magnetic core has the form of substantially a rectangle with rounded corners. Apart from a small air gap 3 it has a closed circumferential contour, which is why it can well be described as a ring-shaped magnetic core 1. The ring shape of the core defines a plane 4 in which the ring-shaped core 1 lies. The cross in the circle 2 indicates the direction perpendicular to the plane 4 of the ring-shaped core 1. The direction perpendicular to the plane 4 is called the axial direction of the ring-shaped core.

In the figure the primary conductor has a direction perpendicular to the plane 4. Of course it could also have a direction with an angle different from 90° to the plane 4, in a way inclined to the plane 4.

The arrow 5 indicates a direction perpendicular to the axial direction 2 of the core 1, which is defined by the center of the core and the position of the air gap 3. This is called the radial direction 5. The arrow 6 indicates a direction which is defined by being perpendicular to both the axial and the radial direction. This is called the circumferential direction 6.

As already mentioned, the core 1 has an air-gap 3. The cross-sectional area of the air-gap is oriented perpendicularly to the circumferential direction 6 of the core 1. Thus, the cross-sectional area of the air-gap 3 is as large as the cross-sectional area of the magnetic core 1, and it cannot be made larger. Within the air-gap 3 the main direction of the magnetic field is oriented perpendicular to the cross-sectional area of the air gap 3 (i.e., along the circumferential direction 6 of the core 1).

The air-gap 3 contains a sensor element 7 for the measurement of the magnetic core induction. The sensor element may be a Hall-sensor, an integrated circuit based Hall sensor, a magnetoresistive sensor or a fluxgate sensor. It can be seen that the current sensor applies a flat shaped air gap 3 and a flat-shaped sensor element 7. In the embodiment shown in FIG. 1a, on the left hand side of FIG. 1, the connection pins 8 of the sensor element 7 are pointing into the radial direction 5. In the embodiment shown in FIG. 1b, on the right-hand side of FIG. 1, the connection pins 8 of the sensor element 7 are pointing into the axial direction 2.

When the magnetic core arrangement as shown in FIG. 1 is used in a closed-loop current sensor, the magnetic core 1 is provided with a secondary winding which carries a compensation current. The purpose of the compensation current is to counteract the magnetic flux density generated by the primary current such that nearly zero-flux operation is ensured both at AC and DC. For this purpose the flux sensor element 7 located in the air-gap 3, will detect any magnetic flux induced in this circuit and will generate a proportional signal. This signal is amplified by some electronic power stage (not shown in the figures), called booster circuit, which will generate the current through the secondary winding. The secondary current is thus opposed to the primary current, establishing a negative feedback, and will compensate its effect on the magnetic circuit.

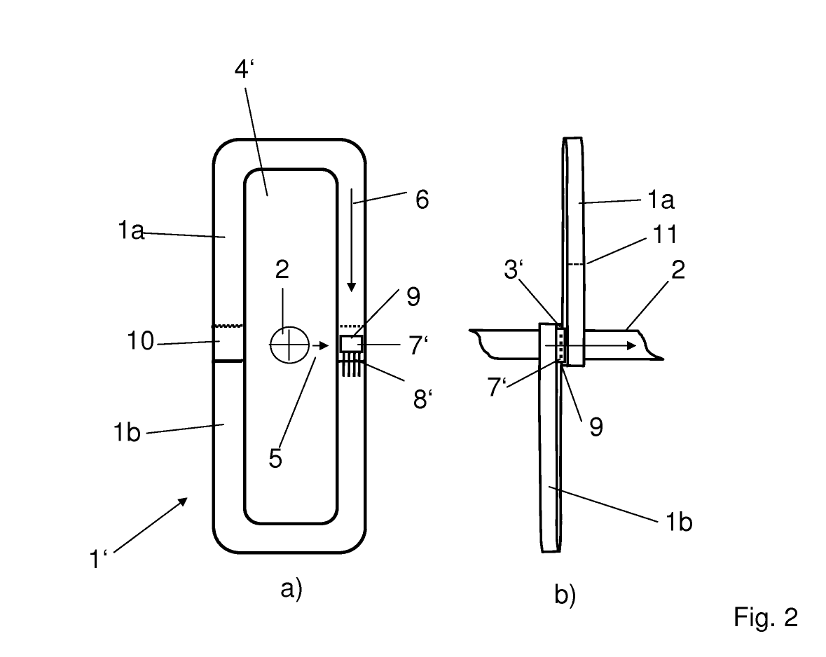

FIG. 2 shows a core design with a sensor 7′ in the air-gap 3′ according to a first exemplary embodiment as disclosed herein. The core 1′ is composed of a first and a second part 1a, 1b, said first and second parts 1a, 1b, when assembled, form the ring-shaped core 1′. The first and second parts 1a, 1b overlap in a first and a second overlap region 9, 10 with a first and a second overlap area. The first overlap region 9 forms the air gap 3′ which is configured to contain the sensor element 7′. In FIG. 2a on the left hand side the connection pins 8′ of the sensor element 7′ are directed along the circumferential direction 6 of the core 1′. Alternatively, they can be also directed along the radial direction, as in FIG. 1b, or in any direction in between. The second overlap region 10 provides a direct contact between the first and the second parts 1a and 1b.

The ring-shaped core 1′ may be either of a circular, an ovaloid or a rectangular shape. In FIG. 2a, left hand side, the view along the axial direction of the ring-shaped core 1′ is shown, where the core has a substantially rectangular shape with rounded corners. FIG. 2b on the right-hand side shows a view along the radial direction of the gap, showing the assembly of the core 1′ from the two overlapping parts 1a and 1b. In this case, the core has an oval shape and the pins of the sensor element are directed along the radial direction. It can be seen that the direction of the air-gap 3′ formed in the first overlap region 9 is oriented in the axial direction 2 of the core 1′. This makes it possible that the area of the first overlap region 9 is larger than the cross-section of the core (which is indicated by the line 11 in FIG. 2b), and so also the cross-section of the air-gap 3′ formed in the overlap region 9 is larger than the cross-section 11 of the core 1′.

Each of the first and second core parts 1a, 1b is a stacked core part, made from one or several sheets of magnetic material, which, when assembled to the core 1′ form a ring-shaped structure that encloses the primary conductor 2 and which overlap in two plane overlap regions 9, 10 of the core.

By using non-symmetric parts the overlap area in the second overlap region 10 can be made larger than the overlap area in the first overlap region 9 which results in an improvement of the flux transition in the second overlap region 10.

An exemplary advantage of a sensor configuration as disclosed herein is that the cross section of the air gap is larger than the core cross section and sufficiently large to provide a good coverage and shielding of the sensor element.

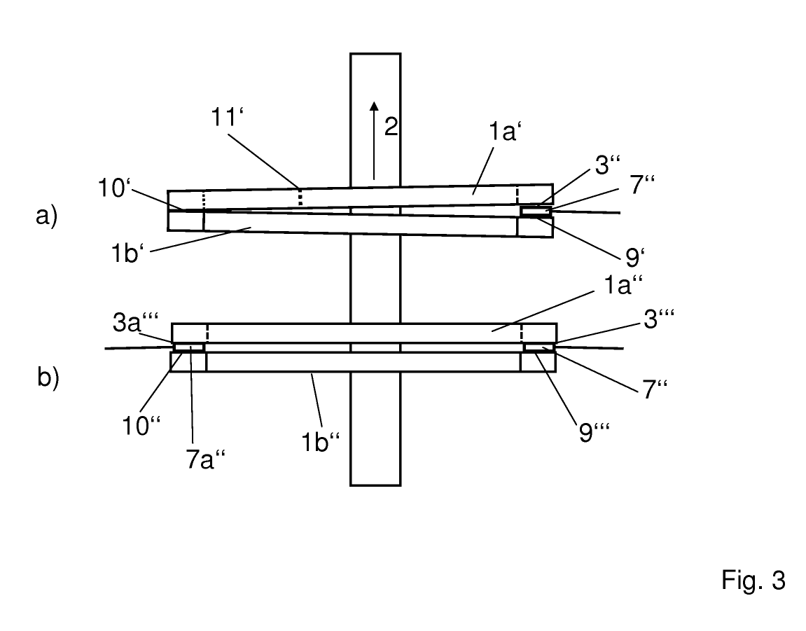

FIG. 3a shows a further exemplary embodiment, where the two core parts 1a′, 1b′, which can be produced from stacked, strip-wound or bulk, e.g. ferrite material, are planar and unbent. They are mounted on top of each other with two overlap regions 9′, 10′. The first overlap region 9′ forms a gap 3″, which contains the flux sensor element 7″, while the second overlap region 10′ makes a direct contact between the first and second part 1a′, 1b′. This is achieved by tilting one of the core-parts 1a′, 1b′ with respect to the other, which leads to a gap and a contact which have end faces that are not fully parallel to each other. In order to keep the inclination small, this method is preferably used with elongated, where the overlap regions are on the short sides of the core cores.

FIG. 3b shows a further exemplary embodiment where the planar core parts 1a″, 1b″are mounted on top of each other with a parallel orientation, such that equal gaps 3′″, 3a′″ are formed in the overlap regions 9″, 10″. The gap 3a′″ in the second overlap region 10″ can be filled either with a second sensor 7a″ (shown in FIG. 3b), a nonmagnetic spacer or with soft magnetic material, which will magnetically short-circuit the gap. In the two configurations, the cross section of the overlaps 9′, 10′, 9″, 10″ can be made larger than the core cross section 11′.

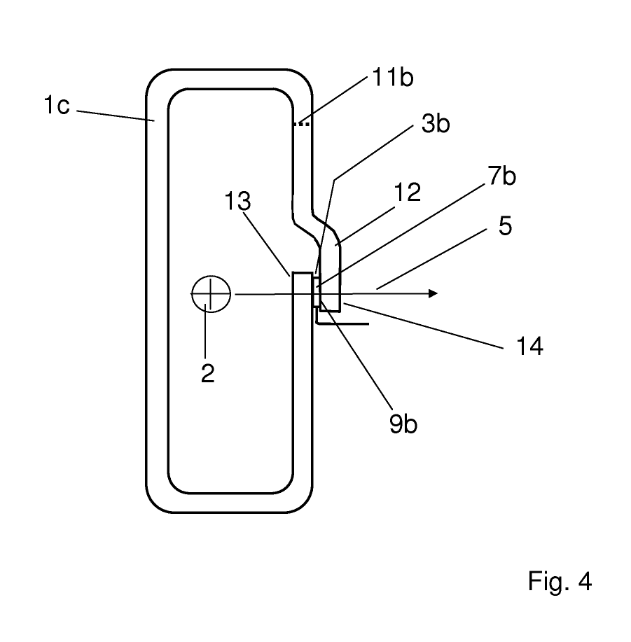

FIG. 4 shows a further exemplary embodiment. It shows a core configuration, in which the air gap 3b and the sensitive axis of the sensor element 7b are oriented in the radial direction 5 of the core 1c. The ring shaped core 1c, which may have a mainly circular, ovaloid or rectangular shape (in FIG. 4a mainly rectangular shape is shown), is made from stacked core sheets or from a few layers of thin strip-wound magnetic tape, which form a ring-shaped structure enclosing the primary conductor 2. The two end parts 13, 14 of the core 1c overlap in a plane region 9b, where they form an air gap 3b that fully encloses the sensor element 7b. The core 1c has a curved part 12, formed by a local bend, to generate the required overlap 9b. The two end pieces 13, 14 of the core 1c forming the overlap region 9b can be fixed by resin impregnation, spot welding, moulding, plastic encapsulation, or other suitable means. The cross section of the overlap 9b can be made larger than the core cross section 11b.

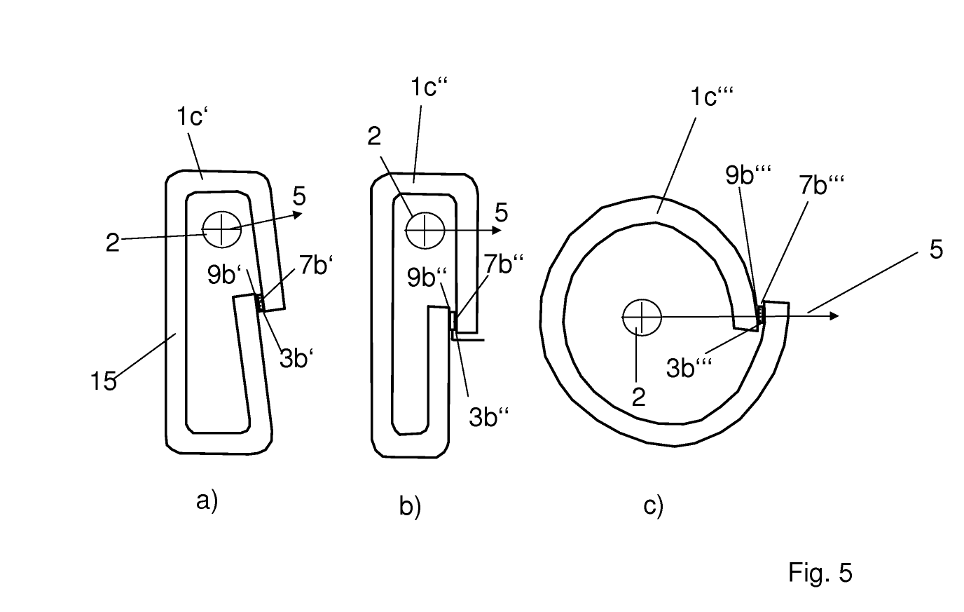

FIG. 5 a, b and c show alternative exemplary embodiments of the configuration, in which the air gaps 3b′, 3b″, 3b″ and the sensitive axis of the sensor element 7b′, 7b″, 7b″ are oriented in the radial direction 5 of the core 1b′, 1b″, 1b′″. In the configurations of FIG. 5a and b there is no curved part and no local bend close to the overlap region 9b′, 9b″. FIG. 5a shows an embodiment where the core has a substantially rectangular shape, the overlapping end-pieces of the core are tilted with respect to the opposite lying longitudinal branch 15. In the configuration of FIG. 5b the core has a substantially rectangular shape, the overlapping end-pieces of the core are in parallel to the branch 15. In the configuration of FIG. 5c the core has a substantially circular shape.

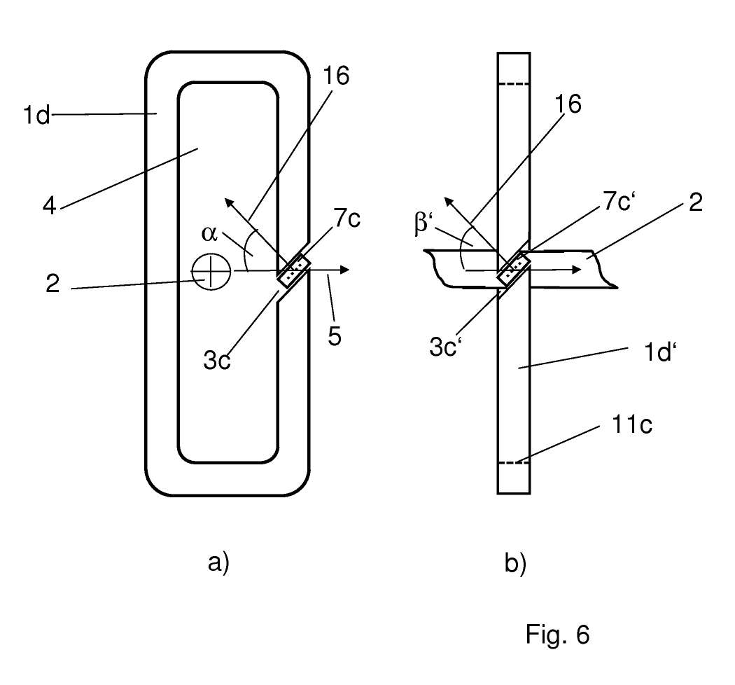

FIG. 6 shows an exemplary embodiment with configurations, where the air gap is rotated by some angle around the axial or the radial axis. In FIG. 6a the air gap 3c and the sensitive axis 16 of the sensor element 7c are rotated by an angle α around the axial direction 5 of the core 1d. In FIG. 6b the gap 3c′ and the sensitive axis 16′ of the sensor element 7c′ are rotated by an angle β around the radial direction. Any combination of such rotations is also possible. Here, the cores 1d, 1d′ have a substantially rectangular shape, other forms are also possible. FIG. 6a shows a view along the axial direction of core 1d, while FIG. 6b shows a view along the radial direction of the gap of core 1d′. The angles α or β may be around 45°, but any other angle between 10° and 80° (or more or less) are also possible. Also, any combination of α and β from the given ranges plus 90° (the usual gap orientation) is possible. The core 1d may be based on strip-wound, stacked or bulk material, which can be fixed by the aforementioned, or other suitable, methods.

The overlapping areas in the regions of the air-gaps 3c, 3c′ are created by a tilted cutting of the cores 1d, 1d′. Due to the tilting of the air gaps their cross-sectional area is larger than the cross-sectional area of the core.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

FIGURE legend:

| | |
|---|---|
| 1, 1′ | Magnetic core |
| 1a, 1a′, 1a″ | First part of core 1′ |
| 1b, 1b′, 1b″ | Second part of core 1′ |
| 1c, 1c′, 1c″, 1c′″ | Magnetic core |
| 1d, 1d′ | Magnetic core |
| 2 | Primary conductor; axial direction |
| 3, 3′, 3″, 3′″, 3a′″, 3b, 3b′, 3b″, 3b′″, | Air gap |
| 3c, 3c′ | |
| 4 | Plane |
| 5 | Radial direction |
| 6 | Circumferential direction |
| 7, 7′, 7″, 7a″, 7b, 7b′, 7b″, 7b′″, 7c, | Sensor element |
| 7c′ | |
| 8, 8′ | Connection pin |
| 9, 9′, 9″ | First overlap region |
| 9b, 9b′, 9b″, 9b′″ | Overlap region |
| 10, 10′, 10″ | Second overlap region |
| 11, 11′, 11b, 11c | Cross-section of core 1′ |
| 12 | Curved part |
| 13 | End piece |
| 14 | End piece |
| 15 | Longitudinal branch |
| 16, 16′ | Sensitive axis of sensor element |

1. Current sensor, comprising:
a ring-shaped magnetic core, said core enclosing a primary conductor for carrying current to be measured, said core having an air-gap; and
a sensor element of said air-gap for measuring magnetic core induction, wherein a cross-sectional area of the air-gap is larger than a cross-sectional area of the core.

2. Current sensor according to claim 1, wherein a direction of the air-gap is oriented in an axial direction of the ring-shaped magnetic core.

3. Current sensor according to claim 2, whereby the core comprises:
at least one overlap region where a first end piece and a second end piece overlap forming an overlap region when the core is assembled in its ring-shaped form, said overlap region forming the air-gap which is configured to contain the sensor element.

4. Current sensor according to claim 3, whereby the core comprises:
a first part and a second part, said first and second parts, when assembled, forming the ring-shaped core, and said first and second parts overlapping in a first overlap region and a second overlap region with a first overlap area and a second overlap area, whereby said first overlap region forms the air-gap which is configured to contain the sensor element, and whereby said second overlap region provides direct contact between the first part and the second part.

5. Current sensor according to claim 4, whereby the overlap area in the second overlap region is larger than the overlap area in the first overlap region.

6. Current sensor according to claim 4, whereby the first and second overlap regions form first and second gaps, whereby the first gap is configured as air-gap to contain the sensor element, and the second gap is filled with a soft magnetic spacer means for magnetically short-circuiting the second gap.

7. Current sensor according to claim 1, whereby the ring-shaped core comprises:
a first, ungapped partial core and a second partial core having the air-gap, said air-gap containing the sensor element for measuring the magnetic core induction, whereby the cross-sectional area of the air-gap is larger than the cross-sectional area of the second partial core, first and second partial cores forming a combined magnetic core that can be provided with a common secondary winding.

8. Current sensor according to claim 7, whereby the first partial core comprises:
a larger core cross section than the second partial core and is made from a high saturation magnetic material.

9. Current sensor according to claim 1, whereby a direction of the air-gap is oriented in a radial direction of the ring-shaped core.

10. Current sensor according to claim 1, whereby a direction of the air-gap forms an angle with a axial direction of the ring-shaped core, which is not equal to 90°.

11. Current sensor according to claim 1, whereby a direction of the air-gap forms an angle with a radial direction of the ring-shaped core, which is not equal to 90°.

12. Current sensor according to claim 10, whereby the angle is between 10° and 80°.

13. Current sensor according to claim 11, whereby the angle is between 10° and 80°.

14. Current sensor according to claim 1, whereby the core is formed of stacked core sheets.

15. Current sensor according to claim 6, whereby the spacer means is made of a nonmagnetic spacer material or a second flux sensor.
